(19) United States
(12) Patent Application Publication
(10) Pub. No.: US 2026/0136974 A1
(43) Pub. Date: May 14, 2026

(54) PACKAGE SUBSTRATE AND SEMICONDUCTOR PACKAGE INCLUDING THE SAME

(71) Applicant: SAMSUNG ELECTRONICS CO., LTD., Suwon-si (KR)

(72) Inventor: Gyeongah LEE, Suwon-si (KR)

(73) Assignee: SAMSUNG ELECTRONICS CO., LTD., Suwon-si (KR)

(21) Appl. No.: 19/364,594

(22) Filed: Oct. 21, 2025

(30) Foreign Application Priority Data
Nov. 11, 2024 (KR) 10-2024-0159386

(51) Int. Cl. H01L 23/498; H01L 21/48; H01L 23/00; H01L 23/31; H01L 23/538

(52) U.S. Cl. CPC H10W 70/685; H10W 70/05; H10W 70/095; H10W 70/611; H10W 70/65; H10W 70/69; H10W 74/117; H10W 90/724

(57) ABSTRACT

A package substrate includes a first protective layer, an insulation layer structure on the first protective layer, wirings stacked in a vertical direction in the insulation layer structure, thin glass plates between the wirings in the insulation layer structure and being spaced apart from each other in the vertical direction, vias provided between and contacting the wirings in the insulation layer structure and being spaced apart from the thin glass plates in a horizontal direction, and a second protective layer on the insulation layer structure.

### CROSS-REFERENCE TO RELATED APPLICATION

This application is based on and claims priority under 35 U.S.C. § 119 to Korean Patent Application No. 10-2024-0159386, filed on Nov. 11, 2024 in the Korean Intellectual Property Office (KIPO), the contents of which are herein incorporated by reference in their entirety.

### BACKGROUND

### 1. Field

The disclosure relates to a package substrate and a semiconductor package including the package substrate.

### 2. Description of the Related Art

A semiconductor package includes a package substrate and a semiconductor chip on the package substrate. The package substrate includes insulation layers stacked in a vertical direction and wirings and vias in the insulation layers. If the package substrate has a low stiffness, warpage may occur in the package substrate, and thus a method of preventing the warpage is needed.

### SUMMARY

Aspects of the disclosure provide a package substrate having enhanced electrical characteristics.

Aspects of the disclosure provide a semiconductor package having enhanced electrical characteristics.

According to an aspect of the disclosure, there is provided a package substrate including: a first protective layer; an insulation layer structure on the first protective layer; a plurality of wirings spaced apart from each other in a vertical direction in the insulation layer structure; a plurality of thin glass plates between the plurality of wirings in the insulation layer structure, the plurality of thin glass plates being spaced apart from each other in the vertical direction; a plurality of vias contacting the plurality of wirings in the insulation layer structure, the plurality of vias being spaced apart from the plurality of thin glass plates in a horizontal direction; and a second protective layer on the insulation layer structure.

According to an aspect of the disclosure, there is provided a package substrate including: a first protective layer and a second protective layer spaced apart from each other in a vertical direction; an insulation layer structure between the first and second protective layers, the insulation layer structure including first insulation layers and second insulation layers alternately and repeatedly stacked in the vertical direction; a plurality of wirings provided in the first insulation layers, respectively; a plurality of thin glass plates provided in at least two of the second insulation layers; and a plurality of vias extending through upper portions of corresponding ones of the first insulation layers, respectively, and corresponding ones of the second insulation layers, respectively, the corresponding ones of the second insulation layers provided on the corresponding ones of the first insulation layers, respectively, wherein the plurality of vias contacting the plurality of wirings.

According to an aspect of the disclosure, there is provided a semiconductor package including: a package substrate including: a first protective layer; an insulation layer structure on the first protective layer; a plurality of wirings spaced apart from each other in a vertical direction in the insulation layer structure; a plurality of thin glass plates between the plurality of wirings in the insulation layer structure, the plurality of thin glass plates being spaced apart from each other in the vertical direction; a plurality of vias contacting the plurality of wirings in the insulation layer structure, the plurality of vias being spaced apart from the plurality of thin glass plates in a horizontal direction; and a second protective layer on the insulation layer structure and having an opening exposing an upper surface of a portion of an uppermost one of the plurality of wirings; a semiconductor chip on the package substrate; a conductive connection member contacting the upper surface of the portion of the uppermost one of the wirings and a lower surface of the semiconductor chip; and a molding member on the package substrate, the semiconductor chip and a sidewall of the conductive connection member.

The package substrate according to an example embodiment may have an increased stiffness, and warpage may not occur in the package substrate. Thus, the package substrate and the semiconductor package including the same may have enhanced structural stability and electrical characteristics.

### BRIEF DESCRIPTION OF DRAWINGS

FIG. 1 is a cross-sectional view illustrating a package substrate according to an example embodiment.

FIGS. 2 to 5 are cross-sectional views illustrating a method of manufacturing a package substrate according to an example embodiment.

FIG. 6 is a cross-sectional view illustrating a package substrate according to an example embodiment.

FIG. 7 is a cross-sectional view illustrating a package substrate according to an example embodiment.

FIG. 8 is a cross-sectional view illustrating a semiconductor package according to an example embodiment.

FIG. 9 is a cross-sectional view illustrating an electronic device according to an example embodiment.

### DETAILED DESCRIPTION

Hereinafter, example embodiments will be explained in detail with reference to the accompanying drawings. However, the present disclosure may be implemented in many different forms, and should not be interpreted to be limited to the embodiments elaborated herein.

It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

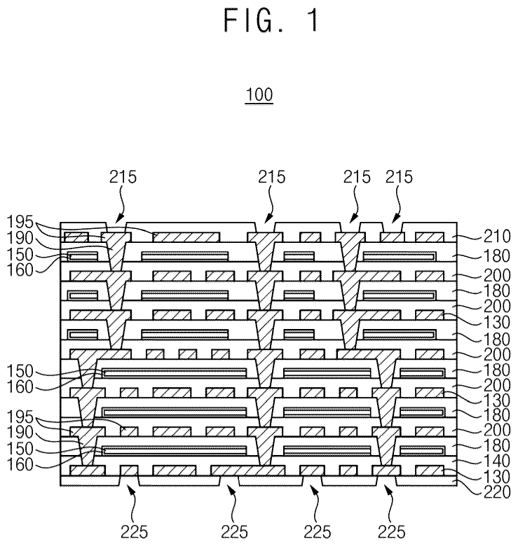

FIG. 1 is a cross-sectional view illustrating a package substrate according to an example embodiment.

Referring to FIG. 1, a package substrate 100 may include a first protective layer 210 and a second protective layer 220, a first insulation layer 140, a second insulation layer 180, a third insulation layer 200, a first via 190, a first wiring 130, a second wiring 195, a thin glass plate 150 and a bonding layer 160.

According to an example embodiment, the first insulation layer 140 may be provided on the second protective layer 220, and the second and third insulation layers 180 and 200 may be alternately and repeatedly stacked on the first insulation layer 140 in the vertical direction. FIG. 1 shows that the second insulation layers 180 are provided at six levels, respectively, and the third insulation layers 200 are provided at five levels, respectively, on the first insulation layer 140, however, the disclosure is not limited thereto, and as such, according to another embodiment, the second insulation layer 180 may be provided at more or less than six levels and the third insulation layer 200 may be provided at more or less than five levels. The first to third insulation layers 140, 180 and 200 stacked in the vertical direction may form an insulation layer structure.

Each of the first to third insulation layers 140, 180 and 200 may include an insulating material. The insulating material may include, but is not limited to, Ajinomoto build-up film (ABF). According to an example embodiment, the first to third insulation layers 140, 180 and 200 may include substantially the same material as each other. As such, the first to third insulation layers 140, 180 and 200 may be merged with each other, and thus the first to third insulation layers 140, 180 and 200 may not be differentiated from each other. In another embodiment, the first to third insulation layers 140, 180 and 200 may include different materials from each other, or may include substantially the same material as each other but may be differentiated from each other by a natural oxide layer therebetween. For example, the first insulation layer 140 may include a first material, the second insulation layer 180 may include a second material different from the first material and the third insulation layer 200 may include a third material different material different from the first material and the second material. In another example, the first insulation layer 140 may include a first material, the second insulation layer 180 may include a second material different from the first material and the third insulation layer 200 may include the first material.

The first wiring 130 may be provided at a lower portion of the first insulation layer 140, and the first insulation layer 140 may be provided on a sidewall and an upper surface of the first wiring 130. For example, the first insulation layer 140 may cover the sidewall and the upper surface of the first wiring 130. According to an example embodiment, a plurality of first wirings 130 may be spaced apart from each other in a horizontal direction in the first insulation layer 140. In the example embodiments of the disclosure, the terms “lower” and “upper” are used based on the orientation of the package structure illustrated in FIG. 1. However, the disclosure is not limited thereto, and as such, in an example case in which the orientation of the package structure is rotated 180 degrees (or flipped), the terms “lower” and “upper” may be reversed.

The second wiring 195 may contact an upper surface of the second insulation layer 180, and may be provided at a lower portion of the third insulation layer 200, and the third insulation layer 200 may be provided on a sidewall and an upper surface of the second wiring 195. For example, the third insulation layer 200 may cover the sidewall and the upper surface of the second wiring 195. According to an example embodiment, a plurality of second wirings 195 may be spaced apart from each other in the horizontal direction in the third insulation layer 200.

The first via 190 may extend through an upper portion of the first insulation layer 140 and the second insulation layer 180 to contact an upper surface of one of the first wirings 130 and a lower surface of one of the second wirings 195, or may extend through an upper portion of the third insulation layer 200 and the second insulation layer 180 to contact an upper surface of one of the second wirings 195 that are provided at a relatively low level and a lower surface of one of the second wirings 195 that are provided at a relatively high level. According to an example embodiment, a plurality of first vias 190 may be spaced apart from each other in the horizontal direction.

The first via 190 and the first and second wirings 130 and 195 may form a wiring structure.

Each of the first via 190 and the first and second wirings 130 and 195 may include a metal. The metal may include, but is not limited to, copper, aluminum, etc.

FIG. 1 shows a vertical layout of the first via 190 and the first and second wirings 130 and 195, however, the disclosure is not limited thereto, and the first via 190 and the first and second wirings 130 and 195 may have other vertical layouts. Additionally, the first via 190 and the first and second wirings 130 and 195 may have various horizontal layouts.

The first protective layer 210 may contact an upper surface of an uppermost one of the second insulation layers 180, and the first protective layer 210 may be provided on sidewalls and upper surfaces of the second wirings 195 in the uppermost one of the second insulation layers 180. For example, the first protective layer 210 may cover sidewalls and upper surfaces of the second wirings 195 in the uppermost one of the second insulation layers 180. However, the first protective layer 210 may include a third opening 215 exposing an upper surface of one of the second wirings 195 in the uppermost one of the second insulation layers 180.

The second protective layer 220 may contact a lower surface of the first insulation layer 140, and the second protective layer 220 may be provided on lower surfaces of the first wirings 130 in the first insulation layer 140. For example, second protective layer 220 may cover lower surfaces of the first wirings 130 in the first insulation layer 140. However, the second protective layer 220 may include a fourth opening 225 exposing a lower surface of one of the first wirings 130.

Each of the first and second protective layers 210 and 220 may include solder resist (SR).

The thin glass plate 150 may be provided in each of the second insulation layers 180. Thus, the thin glass plate 150 may not overlap the first wiring 130 in the first insulation layer 140 or the second wiring 195 in the third insulation layer 200 in the horizontal direction. According to an example embodiment, the bonding layer 160 may be provided on a sidewall and upper and lower surfaces of the thin glass plate 150.

According to an example embodiment, a via hole 170 (refer to FIG. 3) may extend through the thin glass plate 150 and the bonding layer 160 provided on the thin glass plate 150, and the first via 190 may be provided in the via hole 170. For example, the bonding layer 160 may cover the thin glass plate 150. Thus, the thin glass plate 150 and the bonding layer 160 may overlap the first via 190 extending through the thin glass plate 150 and the bonding layer 160 in the horizontal direction. The first via 190 may not contact a sidewall of the thin glass plate 150 exposed by the via hole 170. According to an example embodiment, a plurality of via holes 170 may be spaced apart from each other in the horizontal direction.

According to an example embodiment, the thin glass plate 150 and the bonding layer 160 may overlap a corresponding one of the first vias 190 in the horizontal direction. The thin glass plate 150 may be referred to as a thin glass substrate.

The thin glass plate 150 may have a thickness in the vertical direction of about 10 μm to about 20 μm, and the bonding layer 160 may have a thickness in the vertical direction of about 1 μm to about 2 μm.

FIG. 1 shows that one thin glass plate 150 is provided in the second insulation layer 180 at each level, and that the first vias 190 extend through portions of the first and second insulation layers 140 and 180 or the second and third insulation layers 180 and 200 in the via holes 170 that may extend through the thin glass plate 150, however, the disclosure is not limited thereto.

For example, a plurality of thin glass plates 150 may be provided in the second insulation layer 180 at each level, and the first vias 190 may extend not only through the portions of the first and second insulation layers 140 and 180 in the via holes 170 that may extend through the thin glass plate 150, but also through portions of the first and second insulation layers 140 and 180 or the second and third insulation layers 180 and 200 between neighboring ones of the plurality of thin glass plates 150.

The bonding layer 160 may contact a surface of the thin glass plate 150, and may be provided in the second insulation layer 180. The bonding layer 160 may also contact an upper surface of the first insulation layer 140 or an upper surface of the third insulation layer 200. The bonding layer 160 may increase a bonding force between the thin glass plate 150 and each of the first to third insulation layers 140, 180 and 200. The bonding layer 160 may not be provided on a portion of a sidewall of the thin glass plate 150 that is exposed by the via hole 170.

The bonding layer 160 may include an insulating material. The insulating material may include, but is not limited to, silicon nitride, silicon carbonitride, silicon oxide, etc.

As illustrated above, the package substrate 100 may include the insulation layer structure having the first to third insulation layers 140, 180 and 200 stacked in the vertical direction, the wiring structure including the first via 190 and the first and second wirings 130 and 195 in the insulation layer structure, and the thin glass plate 150 in the second insulation layer 180.

According to an embodiment, the package substrate 100 may not include a core. However, the thin glass plate 150 may have a stiffness greater than a stiffness of each of the first to third insulation layers 140, 180 and 200 so that the package substrate 100 including the thin glass plate 100 may have an increased stiffness. Accordingly, warpage may not occur in the package substrate 100, so that the package substrate 100 may have enhanced structural stability.

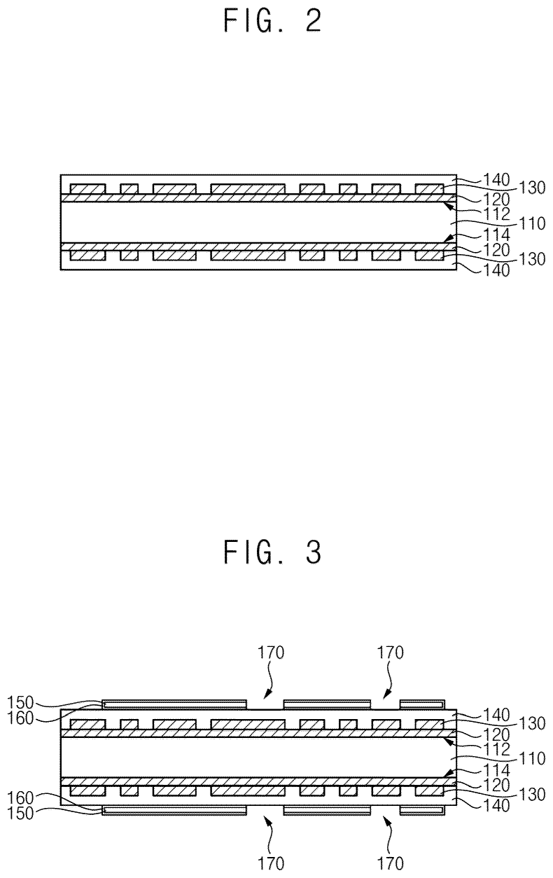

FIGS. 2 to 5 are cross-sectional views illustrating a method of manufacturing a package substrate according to an example embodiment.

Referring to FIG. 2, the method may include forming seed layers 120 on first and second surfaces 112 and 114, respectively, of a detach core 110. The first and second surfaces are opposite to each other in the vertical direction. Moreover, the method may include forming first wirings 130 on upper and lower surfaces of the seed layers 120, respectively, and forming first insulation layers 140 on the upper and lower surfaces of the seed layers 120, respectively. For example, the first insulation layers 140 may be formed on the upper and lower surfaces of the seed layers 120 to cover the first wirings 130.

According to an example embodiment, the detach core 110 may include a mixture of glass fiber and epoxy resin. However, the disclosure is not limited thereto, and as such, the detach core 110 may include one or more other materials.

According to an example embodiment, the first wirings 130 may be formed by an electroplating process or an electroless plating process, and the first insulation layers 140 may be formed by a lamination process or a coating process.

According to an example embodiment, a detach bonding layer may be further formed between the detach core 110 and each of the seed layers 120.

Referring to FIG. 3, the method may include forming a bonding layer 160 on a surface of each of the thin glass plates 150, forming a via hole 170 through the bonding layer 160 and each of the thin glass plates 150, and bonding the thin glass plates 150 to upper and lower surfaces of the first insulation layers 140, respectively, via the bonding layers 160.

According to an example embodiment, the bonding layer 160 may be formed on the surface of each of the thin glass plates 150 by a deposition process. The deposition process may include, but is not limited to, a chemical vapor deposition (CVD) process, an atomic layer deposition (ALD) process, etc.

According to an example embodiment, the via hole 170 may be formed by a drilling process. The drilling process may include, but is not limited to, using a laser drill. According to an embodiment, a plurality of via holes 170 may be spaced apart from each other in the horizontal direction.

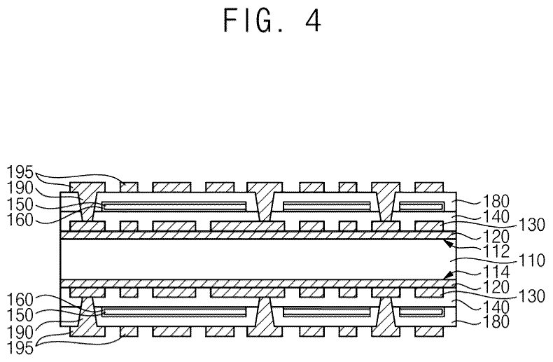

Referring to FIG. 4, the method includes forming second insulation layers 180 on the upper and lower surfaces of the first insulation layers 140, respectively. For example, the second insulation layers 180 may be formed on the upper and lower surfaces of the first insulation layers 140 to cover the thin glass plates 150 and the bonding layers 160. According to an embodiment, the method may include partially removing a first one of the second insulation layers 180 and an upper portion of a first one of the first insulation layers 140 therebeneath and a second one of the second insulation layers 180 and a lower portion of a second one of the first insulation layers 140 thereon to form first openings exposing upper and lower surfaces of the first wirings 130, respectively. According to an embodiment, the method may include forming masks having second openings connected to the first openings, respectively, on upper and lower surfaces of the first and second ones, respectively, of the second insulation layers 180, performing an electroplating process or an electroless plating process to form a first via 190 and a second wiring 195, respectively, and removing the masks.

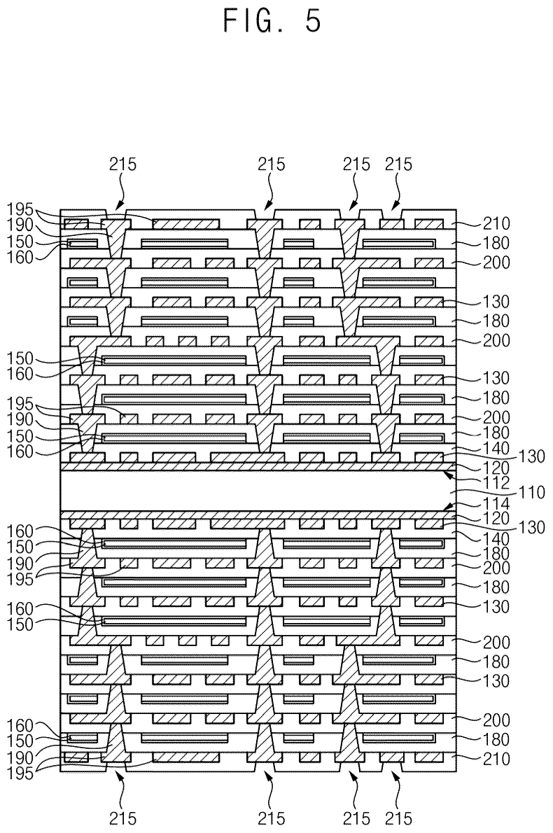

Referring to FIG. 5, third insulation layers 200 may be formed on the upper and lower surfaces of the first and second ones, respectively, of the second insulation layers 180, and processes substantially the same as or similar to those illustrated with respect to FIGS. 3 and 4 may be performed.

Thus, the thin glass plates 150 having the bonding layers 160, respectively, on surfaces thereof, the second insulation layers 180, the first vias 190, the second wirings 195 and the third insulation layers 200 may be stacked in the vertical direction.

First protective layers 210 may be formed on uppermost and lowermost ones of the second insulation layers 180, respectively. For example, the first protective layers 210 may be formed on uppermost and lowermost ones of the second insulation layers 180 to cover the second wirings 195. Each of the first protective layers 210 may have a third opening 215 exposing one of the second wirings 195.

Referring to FIG. 1 again, the detach core 110 may be removed so that stack structures on the first and second surfaces 112 and 114, respectively, of the detach core 110 may be separated from each other, and the seed layers 120 of the stack structures may be removed.

A second protective layer 220 may be formed on a lower surface of the first insulation layer 140. For example, the second protective layer 220 may be formed on the lower surface of the first insulation layer 140 to cover the first wirings 130. The second protective layer 220 may include a fourth opening 225 exposing one of the first wirings 130.

The package substrate 100 may be manufactured by the above processes.

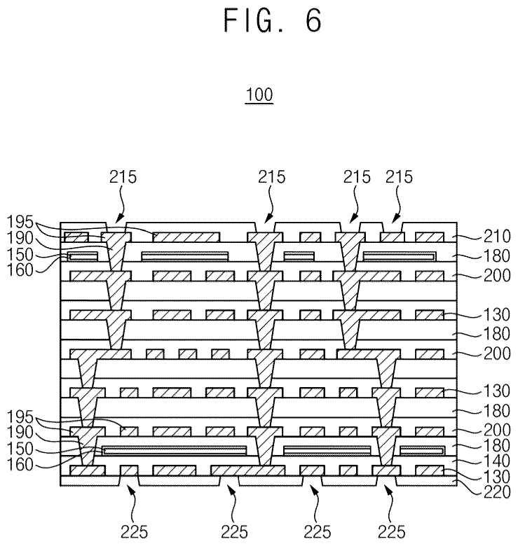

FIG. 6 is a cross-sectional view illustrating a package substrate according to an example embodiment. This package substrate may be substantially the same as or similar to that of FIG. 1, except for the arrangement of the thin glass plate, and thus repeated explanations are omitted herein.

Referring to FIG. 6, the thin glass plate 150 and the bonding layer 160 may be provided only in each of lowermost and uppermost ones of the second insulation layers 180, and may not be provided in other ones of the second insulation layers 180.

Thus, the thin glass plate 150 and the bonding layer 160 may be provided between the first wiring 130 and a lowermost one of the second wirings 195 and between an uppermost one of the second wirings 195 and one of the second wirings 195 at a second level from above, and may not be provided between one of the second wirings at a second level from below and the one of the second wirings at the second level from above.

According to an example embodiment, the thin glass plate 150 and the bonding layer 160 may be provided only in the lowermost one of the second insulation layers 180, or only in the uppermost one of the second insulation layers 180.

The thin glass plate 150 and the bonding layer 160 may not be provided in all of the second insulation layers 180 of the package substrate 100, and thus process time and cost for manufacturing the package substrate 100 may be reduced. The thin glass plate 150 may be provided in the uppermost and lowermost ones of the second insulation layers 180, which may significantly affect the total stiffness of the package substrate 100, so that the package substrate 100 may still have an increased stiffness, and that the warpage of the package substrate 100 may be reduced.

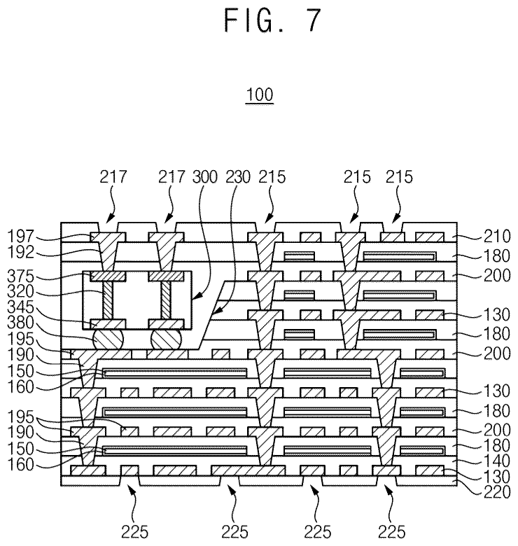

FIG. 7 is a cross-sectional view illustrating a package substrate according to an example embodiment. This package substrate may be substantially the same as or similar to that of FIG. 1, except for further including a bridge, and thus repeated explanations are omitted herein.

Referring to FIG. 7, the package substrate 100 may further include a bridge 300, a first conductive connection member 380, a second via 192 and a third wiring 197.

The bridge 300 may be provided in a cavity 230. For example, the cavity 230 may be formed by removing portions of the second and third insulation layers 180 and 200. According to an embodiment, the portions of the second and third insulation layers 180 and 200 may be removed using excimer laser, but the disclosure is not limited thereto. The first conductive connection member 380 may be provided between the bridge 300 and the second wiring 195. The second via 192 and the third wiring 197 may be provided on the bridge 300.

According to an example embodiment, the bridge 300 may include a semiconductor material. The semiconductor material may include, but is not limited to, silicon, germanium, etc. The bridge 300 may include a through electrode 320 extending in the vertical direction, and first and second conductive pads 345 and 375 contacting lower and upper surfaces, respectively, of the through electrode 320.

Each of the through electrode 320 and the first and second conductive pads 345 and 375 may include a conductive material. The conductive material may include, but is not limited to, a metal, a metal nitride, a metal silicide, etc.

The first conductive pad 345 may contact an upper surface of the first conductive connection member 380, and the second conductive pad 375 may contact a lower surface of the second via 375. The third wiring 197 may contact an upper surface of the second via 192, and an upper surface of the third wiring 197 may be exposed by a fifth opening 217 in the first protective layer 210.

The first conductive connection member 380 may include, but is not limited to, a conductive bump or a conductive ball. The first conductive connection member 380 may include a metal. The metal may include, but is not limited to, tin, or a tin alloy such as solder. The solder may include, but is not limited to, tin and silver, tin and copper, tin and indium, or tin, silver and copper.

As the package substrate 100 further includes the bridge 300, the package substrate 100 may have an increased stiffness, and electrical signals may be transferred through the bridge 300, the first conductive connection member 380, the second via 192 and the third wiring 197.

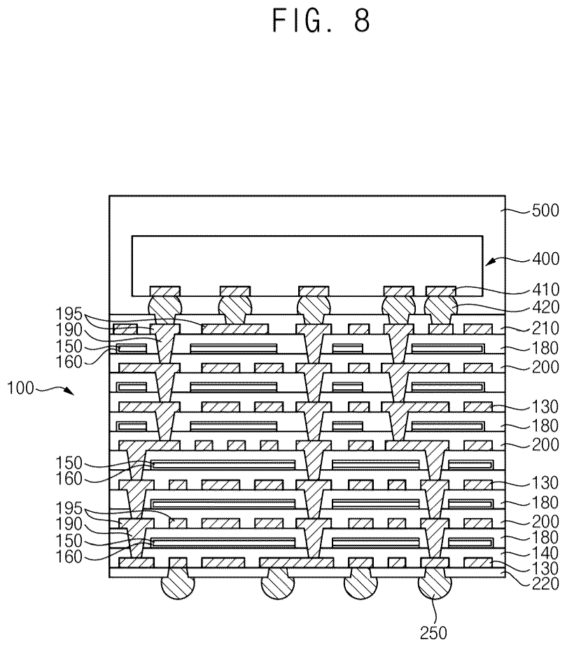

FIG. 8 is a cross-sectional view illustrating a semiconductor package according to an example embodiment. This semiconductor package may include the package substrate of FIG. 1, and thus repeated explanations are omitted herein. This semiconductor package may also include any one of the package substrates shown in FIGS. 6 and 7.

Referring to FIG. 8, the semiconductor package may include the package substrate 100, a semiconductor chip 400 on the first protective layer 210 of the package substrate 100, a second conductive connection member 420 between the first protective layer 210 and the semiconductor chip 400, a molding member 500 provided on the first protective layer 210, the semiconductor chip 400 and the second conductive connection member 420, and a third conductive connection member 250 on a lower surface of the second protective layer 220 of the package substrate 100. The molding member 500 may cover the first protective layer 210, the semiconductor chip 400 and/or the second conductive connection member 420.

The semiconductor chip 400 may be a logic chip including logic device or a memory chip including a memory device. A third conductive pad 410 may be provided on a surface of the semiconductor chip 400, and the second conductive connection member 420 may contact a lower surface of the third conductive pad 410 and an upper surface of the second wiring 195 exposed by the third opening 215 in the first protective layer 210. The second conductive connection member 420 may be a conductive bump or a conductive ball including, but not limited to, solder.

The molding member 500 may include, but is not limited to, epoxy molding compound (EMC).

The third conductive connection member 250 may contact a lower surface of the first wiring 130 exposed by the fourth opening 225 in the second protective layer 220. The third conductive connection member 250 may be a conductive bump or a conductive ball including, but not limited to, solder.

As illustrated above with reference to FIG. 1, the package substrate 100 may have the increased stiffness and structural stability, so that the semiconductor package including the package substrate 100 may also have increased stiffness and structural stability.

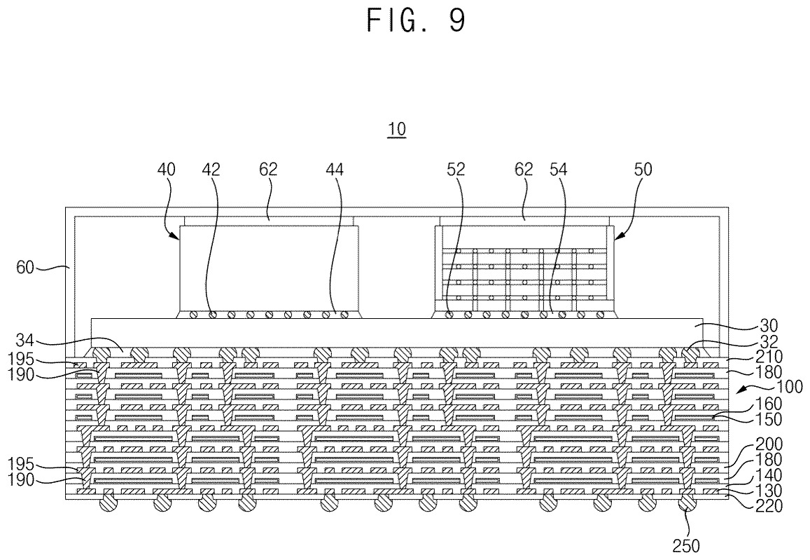

FIG. 9 is a cross-sectional view illustrating an electronic device according to an example embodiment. This electronic device may include the package substrate shown in FIG. 1, and thus repeated explanations are omitted herein. This electronic device may include any one of the package substrates shown in FIGS. 6 and 7.

Referring to FIG. 9, an electronic device 10 may include a package substrate 100, an interposer 30, a first semiconductor device 40 and a second semiconductor device 50. The electronic device 10 may further include a first underfill member 34, a second underfill member 44, a third underfill member 54, a heat slug 60 and a heat dissipation member 62.

According to an example embodiment, the electronic device 10 may be a memory module having a 2.5D package structure, and thus may include the interposer 30 for electrically connecting the first and second semiconductor devices 40 and 50 to each other.

According to an example embodiment, the first semiconductor device 40 may include a logic device, and the second semiconductor device 50 may include a memory device. The logic device may be an application-specific integrated circuit (ASIC) chip including, but not limited to, a central processing unit (CPU), a graphics processing unit (GPU), a micro-processor, a micro-controller, an application processor (AP), a digital signal processing core, etc. The memory device may be a semiconductor package such as an HBM package.

The interposer 30 may be mounted on the package substrate 20 through a fourth conductive connection member 32. According to an example embodiment, a planar area of the interposer 30 may be smaller than a planar area of the package substrate 20. The interposer 30 may be provided within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 or electrically connected to the package substrate 20 through the fourth conductive connection member 32. The fourth conductive connection member 32 may include, but is not limited to, a micro-bump. The silicon interposer may provide a high-density interconnection between the first and second semiconductor devices 40 and 50.

The first semiconductor device 40 may be provided on the interposer 30. The first semiconductor device 40 may be mounted on and bonded with the interposer 30 by a flip chip bonding process. In this case, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through a fifth conductive connection member 42. For example, the fifth conductive connection member 42 may include, but is not limited to, a micro-bump.

Alternatively, the first semiconductor device 40 may be mounted on the interposer 30 by a wire bonding process, and in this case, the active surface of the first semiconductor device 40 may face upwardly.

The second semiconductor device 50 may be provided on the interposer 30, and may be spaced apart from the first semiconductor device 40 in the horizontal direction. The second semiconductor device 50 may be mounted on and bonded with the interposer 30. For example, the second semiconductor device 50 may be mounted on and bonded with the interposer 30 by a flip chip bonding process. In this case, conductive pads of the second semiconductor device 50 may be electrically connected to conductive pads of the interposer 30 by a sixth conductive connection member 52.

Although a single first semiconductor device 40 and a single second semiconductor device 50 are provided on the interposer 30, however, the disclosure is not be limited thereto, and a plurality of first semiconductor devices 40 and/or a plurality of second conductive devices 50 may be provided on the interposer 30.

According to an example embodiment, the first underfill member 34 may fill a space between the interposer 30 and the package substrate 20, and the second and third underfill members 44 and 54 may fill a space between the first semiconductor device 40 and the interposer 30 and a space between the second semiconductor device 50 and the interposer 30, respectively.

The first to third underfill members 34, 44 and 54 may include a material having a relatively high fluidity to effectively fill a small space between the first and second semiconductor devices 40 and 50 and the interposer 30 and a small space between the interposer 30 and the package substrate 20. For example, each of the first and second underfill members 34, 44 and 54 may include an adhesive containing an epoxy material.

The semiconductor device 50 may include a buffer die and a plurality of memory dies sequentially stacked on the buffer die. The buffer die and the memory dies may be electrically connected to each other by through electrodes, and the through electrodes may be electrically connected to each other by conductive bonding pads. For example, the through electrodes may be through-silicon vias (TSVs). Data signals and control signals may be transferred to the buffer die and the memory dies by the through electrodes.

According to an example embodiment, the heat slug 60 may be formed on the package substrate 20 to thermally contact the first and second semiconductor devices 40 and 50. The heat dissipation member 62 may be provided on an upper surface of each of the first and second semiconductor devices 40 and 50, and may include, but is not limited to, thermal interface material (TIM). The heat slug 60 may thermally contact the first and second semiconductor devices 40 and 50 via the heat dissipation member 62.

The electronic device 10 may be mounted on a module substrate through the third conductive connection member 250 to form a memory module.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the inventive concept of the disclosure. Accordingly, all such modifications are intended to be included within the scope of disclosure as defined in the claims.

What is claimed is:

1. A package substrate comprising:
a first protective layer;
an insulation layer structure on the first protective layer;
a plurality of wirings spaced apart from each other in a vertical direction in the insulation layer structure;
a plurality of thin glass plates between the plurality of wirings in the insulation layer structure, the plurality of thin glass plates being spaced apart from each other in the vertical direction;
a plurality of vias contacting the plurality of wirings in the insulation layer structure, the plurality of vias being spaced apart from the plurality of thin glass plates in a horizontal direction; and
a second protective layer on the insulation layer structure.

2. The package substrate according to claim 1, wherein the plurality of thin glass plates are provided between a first wiring, which is a lowermost wiring among the plurality of wirings, and a second wiring among the plurality of wirings, and between a third wiring, which is an uppermost wiring among the plurality of wirings, and a fourth wiring among the plurality of wirings, and
wherein no thin glass plates are provided between the second wiring and the fourth wiring.

3. The package substrate according to claim 1, wherein the plurality of thin glass plates are provided between all adjacent wirings among the plurality of wirings in the vertical direction.

4. The package substrate according to claim 1, wherein the plurality of thin glass plates comprise a plurality of via holes extending through the plurality of thin glass plates, respectively, and
wherein the plurality of vias are provided in corresponding ones of the plurality of via holes, respectively.

5. The package substrate according to claim 1, further comprising a bonding layer contacting lower and upper surfaces of each of the plurality of thin glass plates, the bonding layer comprising an insulating material.

6. The package substrate according to claim 5, wherein the bonding layer comprises silicon nitride, silicon carbonitride, or silicon oxide.

7. The package substrate according to claim 5, wherein the bonding layer contacts a sidewall of each of the plurality of thin glass plates.

8. The package substrate according to claim 1, wherein the plurality of thin glass plates do not overlap the plurality of wirings in the horizontal direction.

9. The package substrate according to claim 1, wherein the insulation layer structure comprises first insulation layers and second insulation layers alternately stacked in the vertical direction,
wherein the plurality of wirings are provided in the first insulation layers, respectively, and
wherein the plurality of thin glass plates are provided in the second insulation layers, respectively.

10. The package substrate according to claim 1, wherein each of the first and second protective layers comprises solder resist (SR), and
wherein the insulation layer structure comprises Ajinomoto build-up film (ABF).

11. A package substrate comprising:
a first protective layer and a second protective layer spaced apart from each other in a vertical direction;
an insulation layer structure between the first and second protective layers, the insulation layer structure comprising first insulation layers and second insulation layers alternately and repeatedly stacked in the vertical direction;
a plurality of wirings provided in the first insulation layers, respectively;
a plurality of thin glass plates provided in at least two of the second insulation layers; and
a plurality of vias extending through upper portions of corresponding ones of the first insulation layers, respectively, and corresponding ones of the second insulation layers, respectively, the corresponding ones of the second insulation layers provided on the corresponding ones of the first insulation layers, respectively,
wherein the plurality of vias contacting the plurality of wirings.

12. The package substrate according to claim 11, wherein the plurality of thin glass plates are provided in a lowermost insulation layer and an uppermost insulation layer, respectively, among the second insulation layers, and
wherein no thin glass plates are provided in one or more of the second insulation layers that are between the lowermost insulation layer and the uppermost insulation layer.

13. The package substrate according to claim 11, wherein the second insulation layers comprises two or more insulation layers, and
wherein the plurality of thin glass plates are provided in all of the second insulation layers.

14. The package substrate according to claim 1, wherein the plurality of thin glass plates comprise a plurality of via holes extending through the plurality of thin glass plates, respectively, and
wherein the plurality of vias are provided in corresponding ones of the plurality of via holes, respectively.

15. The package substrate according to claim 11, further comprising a bonding layer contacting lower and upper surfaces of each of the plurality of thin glass plates, the bonding layer comprising an insulating material.

16. The package substrate according to claim 15, wherein the bonding layer comprises silicon nitride, silicon carbonitride, or silicon oxide.

17. A semiconductor package comprising:
a package substrate comprising:
a first protective layer;
an insulation layer structure on the first protective layer;
a plurality of wirings spaced apart from each other in a vertical direction in the insulation layer structure;
a plurality of thin glass plates between the plurality of wirings in the insulation layer structure, the plurality of thin glass plates being spaced apart from each other in the vertical direction;
a plurality of vias contacting the plurality of wirings in the insulation layer structure, the plurality of vias being spaced apart from the plurality of thin glass plates in a horizontal direction; and
a second protective layer on the insulation layer structure and having an opening exposing an upper surface of a portion of an uppermost one of the plurality of wirings;
a semiconductor chip on the package substrate;
a conductive connection member contacting the upper surface of the portion of the uppermost one of the plurality of wirings and a lower surface of the semiconductor chip; and
a molding member on the package substrate, the semiconductor chip and a sidewall of the conductive connection member.

18. The semiconductor package according to claim 17, wherein the plurality of thin glass plates are provided between a first wiring, which is a lowermost wiring among the plurality of wirings, and a second wiring among the plurality of wirings, and between a third wiring, which is an uppermost wiring among the plurality of wirings, and a fourth wiring among the plurality of wirings, and
wherein no thin glass plates are provided between the second wiring and the fourth wiring.

19. The semiconductor package according to claim 17, wherein the plurality of thin glass plates comprise a plurality of via holes extending through the plurality of thin glass plates, respectively, and
wherein the plurality of vias are provided in corresponding ones of the plurality of via holes, respectively.

20. The package substrate according to claim 17, further comprising a bonding layer contacting lower and upper surfaces of each of the plurality of thin glass plates, the bonding layer comprising silicon nitride, silicon carbonitride, or silicon oxide.
